(19) United States
(12) Patent Application Publication
(10) Pub. No.: US 2026/0123381 A1
(43) Pub. Date: Apr. 30, 2026

(54) SEMICONDUCTOR PACKAGE AND METHOD FOR FORMING THE SAME

(71) Applicant: STATS ChipPAC Management Pte. Ltd., Singapore (SG)

(72) Inventors: ChangOh KIIM, Incheon (KR); JinHee JUNG, Incheon (KR); YoungJoo CHOI, Incheon (KR); HeeSoo LEE, Incheon (KR)

(21) Appl. No.: 19/370,872

(22) Filed: Oct. 28, 2025

(30) Foreign Application Priority Data
Oct. 29, 2024 (CN) 202411521766.4

(51) Int. Cl. H01L 23/00; H01L 21/56; H01L 23/36; H01L 23/482; H01L 23/498

(52) U.S. Cl. CPC H10W 20/40; H10W 40/10; H10W 72/01308; H10W 72/01323; H10W 72/01361; H10W 72/352; H10W 72/387; H10W 74/012; H10W 74/15; H10W 90/701

(57) ABSTRACT

A semiconductor package and a method for forming the same are provided. The method includes: providing a substrate; mounting a semiconductor die on a top surface of the substrate; forming a barrier wall on a peripheral area of a top surface of the semiconductor die; dispensing a first fluid material on the top surface of the semiconductor die, wherein the barrier wall prevents the first fluid material from flowing across it; and curing the first fluid material to form a back side metallization (BSM) layer.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. Many electronic components in the device, such as microprocessors and integrated circuits, generate significant amounts of heat during operation. Excessive heat may degrade performance, reliability, life expectancy of an electronic component and may even cause component failure. Heat sinks, heat spreaders, and other thermal solutions including thermal interface material (TIM) are commonly used for dissipating heat and reducing the operational temperature of the electronic components. However, an efficiency of the existing heat dissipation methods may still be limited.

Therefore, a need exists for a semiconductor package with an improved heat dissipation capacity.

### SUMMARY OF THE INVENTION

An objective of the present application is to provide a method for making a semiconductor package with an improved heat dissipation capacity.

According to an aspect of the present application, a method for forming a semiconductor package is provided. The method may include: providing a substrate; mounting a semiconductor die on a top surface of the substrate; forming a barrier wall on a peripheral area of a top surface of the semiconductor die; dispensing a first fluid material on the top surface of the semiconductor die, wherein the barrier wall prevents the first fluid material from flowing across it; and curing the first fluid material to form a back side metallization (BSM) layer.

According to another aspect of the present application, a semiconductor package is provided. The semiconductor package include: a substrate; a semiconductor die mounted on a top surface of the substrate; a barrier wall formed on a peripheral area of a top surface of the semiconductor die; and a back side metallization (BSM) layer formed on the top surface of the semiconductor die, wherein the BSM layer is enclosed or partially enclosed with the barrier wall.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a microscopic image illustrating a back side metallization (BSM) layer of a semiconductor package.

FIGS. 2A to 2H are top or cross-sectional views illustrating various steps of a method for forming a semiconductor package according to an embodiment of the present application.

FIG. 3 is a cross-sectional view of a semiconductor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

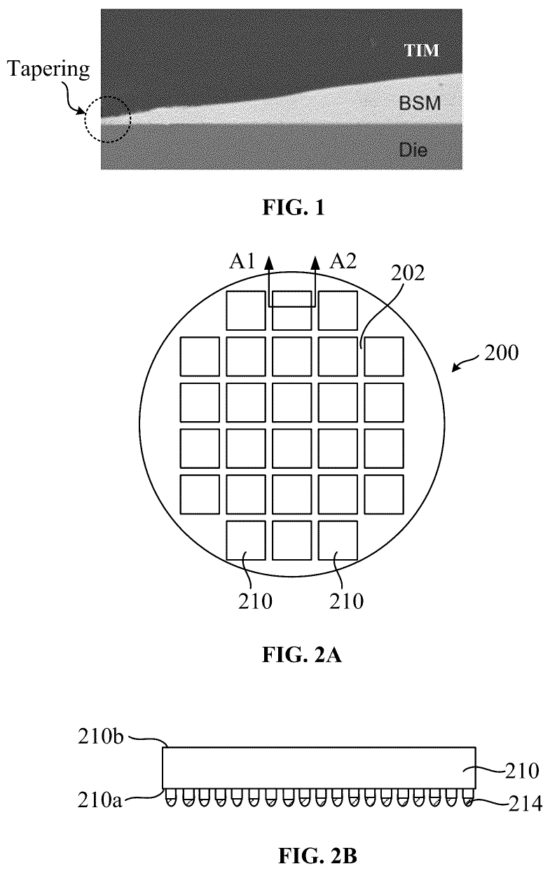

Due to its high thermal conductivity, metal thermal interface material (TIM) has been used in semiconductor packages to improve thermal dissipation performance. Metal TIM requires a back side metallization (BSM) layer formed on a semiconductor die and a surface finish layer formed on a lid to improve bonding performance. Usually, a dispensing technique such as inkjet printing may be employed to form the BSM layer on the semiconductor die. However, as shown in FIG. 1, inventors of the present applicant found that the BSM layer may have a tapering shape in its peripheral regions, which may be caused by a flow property of the material (e.g., an ink composition) used to form the BSM layer. As a result, voids or delamination may occur between the metal TIM layer and the BSM layer and/or between the BSM layer and the semiconductor die, reducing the heat dissipation capacity of the semiconductor package. Further, the inventors of the present applicant found that the BSM layer may be consumed after soldering with the metal TIM layer, and thus more delamination may be induced between the BSM layer and the semiconductor die.

To address at least one of the above problems, a method for forming a semiconductor package is provided. In the method, a barrier wall is formed on a peripheral area of a top surface of a semiconductor die, and the barrier wall can prevent a fluid material used for forming a BSM layer from flowing across it, such that the BSM layer may have a uniform thickness. In some examples, a barrier layer may be formed between the BSM layer and the TIM layer to reduce consumption of the BSM layer during a soldering process. Thus, a heat dissipation capacity of the semiconductor package can be improved.

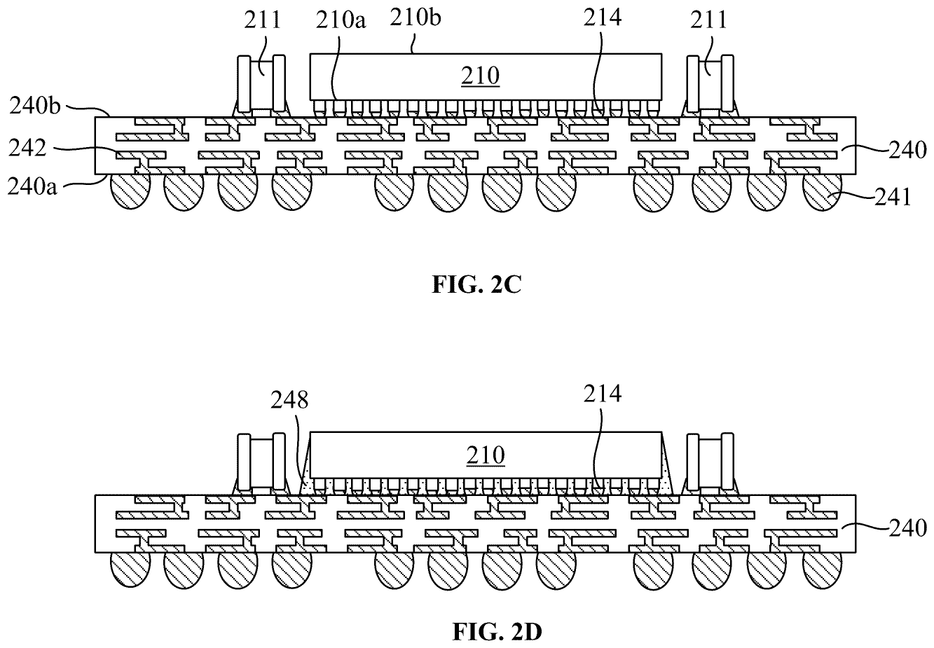

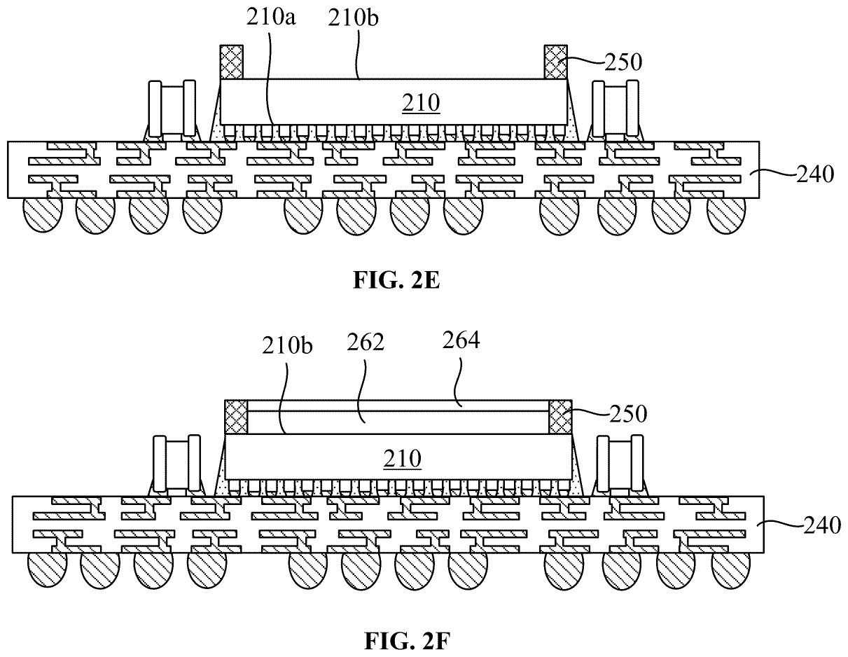

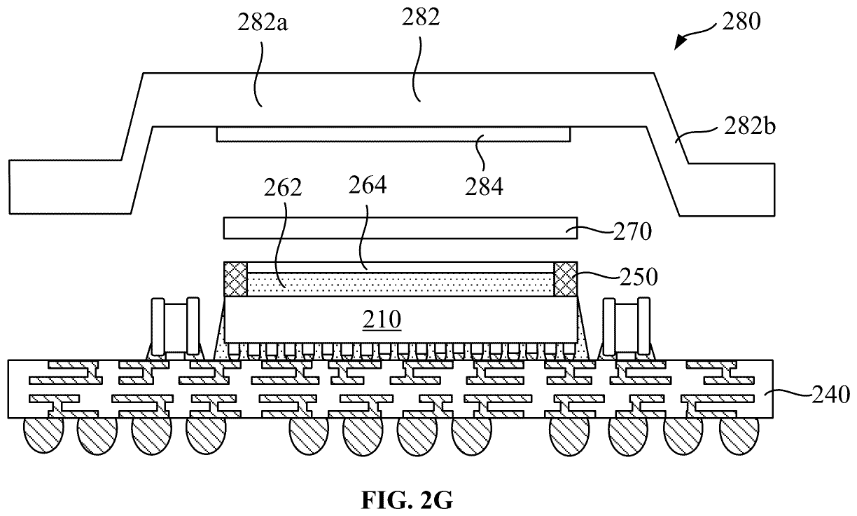

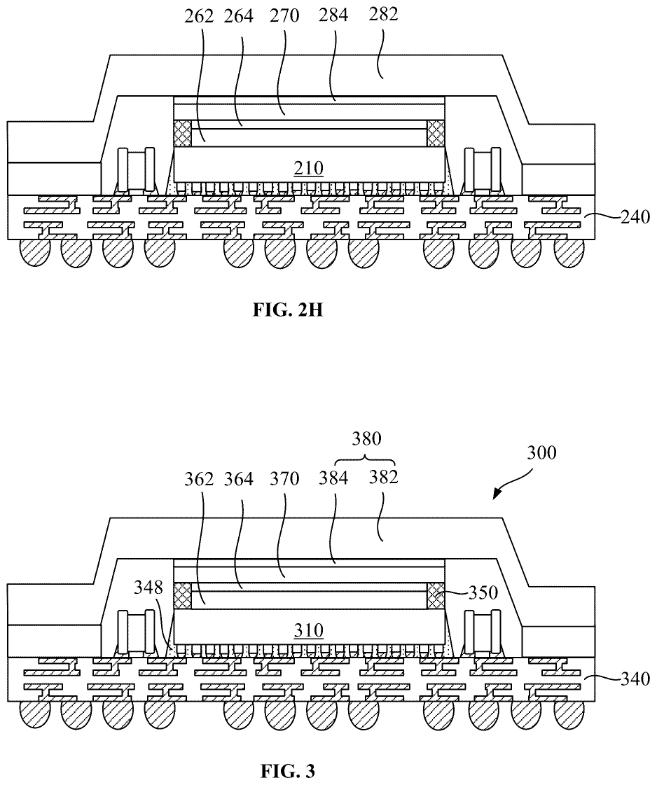

Referring to FIGS. 2A to 2H, various steps of a method for forming a semiconductor package are illustrated. In the following, the method will be described with references to FIGS. 2A to 2H in more details.

As illustrated in FIGS. 2A and 2B, a semiconductor wafer 200 is provided. FIG. 2A is a top view of the semiconductor wafer 200, and FIG. 2B is a cross-sectional view of the semiconductor wafer 200 along a section line A1-A2 shown in FIG. 2A. The semiconductor wafer 200 may include silicon, germanium, gallium arsenide, gallium nitride, indium phosphide, silicon carbide, or other semiconductor material. A plurality of semiconductor dice 210 may be formed on the semiconductor wafer 200 and separated by singulation channels 202. The singulation channels 202 can provide cutting areas to singulate the semiconductor wafer 200 into individual semiconductor dice 210 in a singulation process, as shown in FIG. 2B.

Referring to FIG. 2B, the semiconductor die 210 may have a bottom surface 210a and a top surface 210b. The bottom surface 210a may contain analog or digital circuits implemented as active devices, passive devices, conductive layers, and dielectric layers formed within the semiconductor die 210 and electrically interconnected according to the electrical design and function of the semiconductor die 210. The bottom surface 210a may be an active surface on which a surface fabrication process can be implemented to form one or more of the various types of semiconductor devices as aforementioned. In contrast, the top surface 210b may serve as a support surface to which a carrier may be attached, rather than an active surface as the bottom surface 210a.

In some embodiments, a back-grinding process may be performed on the top surface 210b to reduce the thickness of the semiconductor die 210, since no active devices or circuits are formed on the top surface 210b. In some embodiments, a conductive layer or a redistribution layer may be formed on the bottom surface 210a, and may operate as contact pads electrically connected to the circuits of the bottom surface 210a. In some embodiments, a plurality of interconnection structure 214 such as conductive bumps may be formed on the contact pads. For example, a conductive bump material may be formed on the contact pads to form the interconnect structures 214 as shown in FIG. 2B. It could be understood that the interconnect structure 214 shown in FIG. 2B represent a type of interconnection structure that can be formed on the bottom surface 210a of the semiconductor die 210. However, the present application is not limited thereto, and in other embodiments, the interconnection structure may include a stud bump, a micro bump, or the like.

Referring to FIG. 2C, a substrate 240 is provided, and the semiconductor die 210 is mounted on a top surface 240b of the substrate 240.

The substrate 240 can support the semiconductor die 210 and further connect the semiconductor die 210 with other electronic components mounted thereon. By way of example, the substrate 240 may be a printed circuit board. However, the substrate 240 is not limited thereto. In other examples, the substrate 240 may be a semiconductor substrate, a laminate interposer, a strip interposer, a leadframe, or other suitable substrates. In accordance with the scope of the present application, the substrate 240 may include any structure on or in which integrated circuit systems are fabricated. For example, the substrate 240 may include one or more insulating or passivation layers, one or more conductive vias formed through the insulating layers, and one or more conductive layers formed over or between the insulating layers. In the example shown in FIG. 2C, redistribution structures (RDSs) 242 are formed in the substrate 240, which include a plurality of top conductive patterns on the top surface 240b of the substrate 240, a plurality of bottom conductive patterns on the bottom surface 240a of the substrate 240, and a plurality of conductive vias electrically connecting at least one of the top conductive patterns with at least one of the bottom conductive patterns.

In some embodiments, the semiconductor die 210 may be positioned over the substrate 240 using a pick and place operation with the bottom surface 210a and the interconnect structure 214 oriented toward the substrate 240. The interconnect structure 214 may contact the top conductive pattern of the RDS 242 in the substrate 240. In some embodiments, a laser assisted bonding (LAB) process may be performed to mounted the semiconductor die 210 on the substrate 240. LAB is an advanced flip chip and surface mount bonding technology in which a homogenized laser beam (that is, a two-dimensional beam, not a one-dimensional beam) is selectively applied to a chip or component in order to establish a metallurgical interconnection with a substrate. For example, an irradiation area of the homogenized laser beam may be the same as a size of the semiconductor die 210. An optical energy of the homogenized laser beam can be converted into thermal energy to heat the solder of the interconnect structure 214. Then, the solder can be heated above its melting point and reflowed to form a reliable solder interconnection between the semiconductor die 210 and the substrate 240. The heating temperature can be controlled by the irradiation power and time. As the laser beam can provide more localized heat than a reflow oven and is able to reflow solder with a shorter cycle time, there is a reduced likelihood of damaging the semiconductor die 210 and the interconnect structure 214 during the reflow process. However, the present application is not limited to the above embodiments. In some other embodiments, a mass reflow process or a thermo-compression bonding process may be performed to mount the semiconductor die 210 onto the top surface 240b of the substrate 240.

In some embodiments, as shown in FIG. 2C, other electrical electronic components 211 may also be mounted on the top surface 240b of the substrate 240. The electronic components 211 may include any of a variety of types of semiconductor dice, semiconductor packages, or discrete devices.

Referring to FIG. 2D, an underfill encapsulant 248 is formed between the semiconductor die 210 and the substrate 240 and optionally on side walls of the semiconductor die 210. In some embodiments, the underfill encapsulant 248 may be formed around the interconnect structures 214 between the semiconductor die 210 and the substrate 240. The underfill encapsulant 248 may include a polymer composite material, such as epoxy resin, epoxy acrylate, or polymer with or without a filler. In some examples, the underfill encapsulant 248 is formed by depositing a fluid material at a location on the substrate 240 that is next to the semiconductor die 210, and allowing capillary action to draw the fluid material into the space between the semiconductor die 210 and the substrate 240. In the example shown in FIG. 2D, the underfill encapsulant 248 also covers portions of sidewalls of the semiconductor die 210. The underfill encapsulant 248 may provide mechanical support to the interconnect structure 214, helping to mitigate the risk of crack or delamination due to differential thermal expansion between the semiconductor die 210 and the substrate 240.

Referring to FIG. 2E, a barrier wall 250 is formed on a peripheral area of the top surface 210b of the semiconductor die 210.

In some embodiments, a directly dispensing apparatus may be used to dispensing a fluid composition including a photocurable material and/or a thermosetting material on the peripheral area of the top surface 210b of the semiconductor die 210, and then the fluid composition may be cured to form the barrier wall 250. Depending on properties of the fluid composition, the fluid material may be cured by an ultraviolet (UV), infrared (IR) or near infrared (NIR) radiation, or under a predetermined temperature for a predetermined period.

For example, an inkjet printing apparatus may be used to form the barrier wall 250 on the semiconductor die 210. The inkjet printing apparatus may include a dispensing nozzle configured for dispensing an ink composition and a light source configured for irradiating a light beam with a predetermined intensity. Specifically, the dispensing nozzle of the inkjet printing apparatus is controlled to produce droplets of the ink composition in the order of several to several tens of micrometers in diameter, which will be projected towards the semiconductor die 210. By moving the semiconductor die 210 or the dispensing nozzle relative to each other, the droplets can be dispensed onto the top surface 210b of the substrate 210 at a location where the barrier wall 250 is to be formed. The light source of the inkjet printing apparatus may be controlled to irradiate a light beam to cure the material in the droplets. By continuously moving the semiconductor die 210 or the dispensing nozzle of the inkjet printing apparatus, dispensing the droplets of the ink composition and curing the droplets with light irradiation, the barrier wall 250 can be formed on the top surface 210b of the semiconductor die 210.

In another example, an aerosol printing apparatus may be used to form the barrier wall 250 on the semiconductor die 210. The aerosol printing apparatus can atomize the fluid via ultrasonic or pneumatic means, so as to produce droplets on the order of one to more micrometers in diameter. The droplets may be entrained in a gas stream and delivered to a print head. At the print head, a sheath gas flow may be introduced to focus the droplets into a tightly collimated beam of material. Then, the combined gas streams may fly out of the print head through a converging nozzle that compresses the aerosol stream to particles or droplets with a small diameter. The jet of droplets may fly out of the print head at a high velocity and impinge upon the top surface 210b of the semiconductor die 210, and the droplets can be continuously dispensed on the top surface 210b of the semiconductor die 210 by moving the print head of the aerosol printing apparatus. Afterwards, the fluid may be cured to form the barrier wall 250.

As the inkjet printing apparatus and the aerosol printing apparatus can accurately control the position and/or the dispensing time of the droplets, the barrier wall 250 can be directly formed at a desired area with a desired shape without any mask, or any photolithography process. It could be understood that the present application is not limited to the above embodiments, and the barrier wall 250 can be formed by any other suitable printing apparatus, such as an electrohydrodynamic (EHD) printing apparatus, a nozzle printing apparatus, or a spray coating apparatus.

In some embodiments, the barrier wall 250 may include solder resist (SR). The solder resist may be made of various photosensitive resin compositions or various heat curable resin compositions. In some embodiments, the barrier wall 250 may include other dielectric/insulating materials having sufficient properties such as hardness, heat resistance, chemical resistance, and/or electrical insulation reliability. In some embodiments, the barrier wall 250 may include epoxy, paste, UV curable material, a fluid comprising a metal precursor, and/or other materials with high viscosity that can be coated by inkjet printing, aerosol printing, EHD printing, nozzle printing, or spray coating techniques.

In some embodiments, as shown in FIG. 2E, the barrier wall 250 may be formed along edges of the top surface 210b of the semiconductor die 210 and have a width ranging from micrometers to millimeters. The barrier wall 250 may have a rectangular cross section, a trapezoidal cross section, or other polygonal-shaped cross sections. In some embodiments, the barrier wall 250 may form a closed or partially closed ring having a square, rectangular, hexagonal, or any other geometric shaped footprints on the top surface 210b of the semiconductor die 210. It could be understood that the present application is not limited to the example shown in FIG. 2E. In some other embodiments, the barrier wall 250 may be formed at other locations on the top surface 210b of the semiconductor die 210 and have different cross sections.

Referring to FIG. 2F, a first fluid material is dispensed on the top surface 210b of the semiconductor die 210, and the first fluid material is cured to form a BSM layer 262.

Specifically, the first fluid material may be dispensed on the surface 210b of the semiconductor die 210 by using an inkjet printing apparatus, an aerosol printing apparatus, an EHD printing apparatus, a nozzle printing apparatus, or a spray coating apparatus. As the barrier wall 250 is previously formed on the peripheral area of the top surface 210b of the semiconductor die 210, the barrier wall 250 can prevent the first fluid material from flowing across it. After the first fluid material is cured by an UV, IR or NIR radiation, or under a predetermined temperature for a predetermined period, the BSM layer 262 can be formed with a generally uniform thickness. That is, the BSM layer 262 doesn't have a tapering shape in its peripheral regions, and can assist a TIM layer formed in subsequent process in adhering to the semiconductor die 210.

In some embodiments, the BSM layer 262 may include one or more materials selected from a group consisting of silver, copper, gold, or aluminum. However, the BSM layer 262 is not limited to the above materials, and may include other high conductive material.

Continuing referring to FIG. 2F, a second fluid material is dispensed on the BSM layer 262, and the second fluid material is cured to form a barrier layer 264. Specifically, the second fluid material may be dispensed on the BSM layer 262 by using an inkjet printing apparatus, an aerosol printing apparatus, an EHD printing apparatus, a nozzle printing apparatus, or a spray coating apparatus. The barrier wall 250 may have a sufficient height to prevent the second fluid material from flowing across it. After the second fluid material is cured by an UV, IR or NIR radiation, or under a predetermined temperature for a predetermined period, the barrier layer 264 can be formed on the BSM layer 262. The barrier layer 264 can reduce consumption of the BSM layer 262 during a subsequent soldering process.

In some embodiments, the barrier layer 264 may include one or more materials selected from a group consisting of nickel, titanium, silicon oxide, aluminum oxide, graphene, boron nitride or molybdenum sulfide. However, the barrier layer 264 is not limited to the above materials, and may include other suitable material.

In the above example, the second fluid material is dispensed after the first fluid material is cured. However, the present application is not limited thereto. In other embodiments, the second fluid material is dispensed on the first fluid material, and then the first fluid material the second fluid material are cured simultaneously.

Referring to FIG. 2G, a TIM layer 270 and a heatsink 280 are provided. In some embodiments, the TIM layer 270 may include indium, or an indiumsilver (InAg) alloy. However, the TIM layer 270 is not limited to the above materials, and may include other materials with a high thermal conductivity. The TIM layer 270 may be pre-formed, and can be attached to the barrier layer 264 and the barrier wall 250. That is, the TIM layer 270 will not directly contact with the BSM layer 262. In an example, a first soldering flux layer may be formed on a bottom surface of the TIM layer 270, and a second soldering flux layer may be formed on a top surface of the TIM layer 270. Thus, the TIM layer 270 can be attached to the barrier layer 264 via the first soldering flux layer and attached to the heatsink 280 via the second soldering flux layer. The first soldering flux layer and the second soldering flux layer can facilitate reflowing of the TIM layer 270 in subsequent processes. In some other embodiments, the TIM layer 270 may be formed on the barrier layer 264 and the barrier wall 250 by using sputtering, electrolytic plating, electroless plating, or other suitable deposition process.

The heatsink 280 may also be referred to as a “heat spreader”. In FIG. 2G, the heatsink 280 includes a lid 282 and a surface finish layer 284 attached to the lid 282. In the example shown in FIG. 2G, the lid 282 includes a top portion 282a and a foot portion 282b. The foot portion 282b may be attached to the substrate 240 using adhesive, solder or other suitable material(s) or techniques. In some embodiments, the lid 282 may include copper, aluminum, nickel or other metal materials. However, the lid 282 is not limited to the above materials, and may include other materials with a high thermal conductivity. In order to facilitate the coupling between the lid 282 and the TIM layer 270, the surface finish layer 284 is formed on the underside of the top portion 282a of the lid 282. The surface finish layer 284 can also prevent oxidation of the lid 282. In the example shown in FIG. 2G, the surface finish layer 284 may be attached to the TIM layer 270 via the second soldering flux layer on the top surface of the TIM layer 270. The surface finish layer 284 may include a suitable material to wet the TIM layer 270. In some embodiments, the surface finish layer 284 may include gold. However, the surface finish layer 284 is not limited to gold, and may include other materials such as silver or indium.

Afterward, referring to FIG. 2H, the TIM layer 270 is reflowed to solder the TIM layer 270 and the barrier layer 264 together, and solder the TIM layer 270 and the surface finish layer 284 together. Specifically, the TIM layer 270 may be heated above its melting point, such that the soldering flux between the TIM layer 270 and the barrier layer 264 may escape into the environment, and the TIM layer 270 and the barrier layer 264 may react and form an intermetallic compound (IMC). The IMC can enhance the adhesion between the TIM layer 270 and the barrier layer 264. Similarly, when the TIM layer 270 is heated above its melting point, the soldering flux between the TIM layer 270 and the surface finish layer 284 may escape into the environment, and the TIM layer 270 and the surface finish layer 284 may react and form another IMC to enhance the adhesion between the TIM layer 270 and the surface finish layer 284. Consequently, the semiconductor die 210 is thermally coupled to the lid 282 via the BSM layer 262, the barrier layer 264, the TIM layer 270 and the surface finish layer 284. As the barrier layer 264 is formed between the BSM layer 262 and the TIM layer 270, the BSM layer 262 would not be consumed after soldering with the TIM layer 270, and the heat dissipation capacity of the semiconductor package can be improved.

According to another aspect of the present application, a semiconductor package is provided. Referring to FIG. 3, a cross-sectional view of a semiconductor package 300 is illustrated according to an embodiment of the present application.

As illustrated in FIG. 3, the semiconductor package 300 may include a substrate 340, and a semiconductor die 310 mounted on a top surface of the substrate 340. A barrier wall 350 is formed on a peripheral area of a top surface of the semiconductor die 310, and a back side metallization (BSM) layer 362 is formed on the top surface of the semiconductor die 350. The BSM layer 362 is enclosed or partially enclosed with the barrier wall 310.

In some embodiments, the semiconductor package 300 may further include a barrier layer 364 formed on the BSM layer 362, and the barrier layer 364 is enclosed or partially enclosed with the barrier wall 350. The BSM layer 362 may include silver, copper, gold or aluminum, and the barrier layer 364 may include nickel, titanium, silicon oxide, aluminum oxide, graphene, boron nitride or molybdenum sulfide.

In some embodiments, the semiconductor package 300 may further include an underfill encapsulant 348 formed between the semiconductor die 310 and the substrate 340.

In some embodiments, the semiconductor package 300 may further include a TIM layer 370 disposed on the barrier layer 364, and a heatsink 380 disposed on the TIM layer 370. The heatsink 380 may include a lid 382 and a surface finish layer 384 attached to the lid 382, and the heatsink 380 is attached to the TIM layer 370 via the surface finish layer 384. The TIM layer 370 may include indium, or an indium-silver alloy.

The semiconductor package 300 may be formed by the method described above with reference to FIGS. 2A to 2H. Thus, more details about the semiconductor package 300 may be referred to the disclosure and drawings about the method disclosed above, and will not will not be elaborated herein.

The discussion herein included numerous illustrative figures that showed various portions of a semiconductor package and a method for making the same. For illustrative clarity, such figures did not show all aspects of each exemplary semiconductor package. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a substrate;
mounting a semiconductor die on a top surface of the substrate;
forming a barrier wall on a peripheral area of a top surface of the semiconductor die;
dispensing a first fluid material on the top surface of the semiconductor die, wherein the barrier wall prevents the first fluid material from flowing across it; and
curing the first fluid material to form a back side metallization (BSM) layer.

2. The method of claim 1, wherein forming the barrier wall on the peripheral area of the top surface of the semiconductor die comprises:
dispensing a fluid composition on the top surface of the semiconductor die by using an inkjet printing apparatus, an aerosol printing apparatus, an electrohydrodynamic (EHD) printing apparatus, a nozzle printing apparatus, or a spray coating apparatus.

3. The method of claim 1, wherein dispensing the first fluid material on the top surface of the semiconductor die comprises:
dispensing the first fluid material by using an inkjet printing apparatus, an aerosol printing apparatus, an electrohydrodynamic (EHD) printing apparatus, a nozzle printing apparatus, or a spray coating apparatus.

4. The method of claim 1, further comprising:
dispensing a second fluid material on the BSM layer, wherein the barrier wall prevents the second fluid material from flowing across it; and
curing the second fluid material to form a barrier layer on the BSM layer.

5. The method of claim 4, wherein dispensing the second fluid material on the BSM layer comprises:
dispensing the second fluid material by using an inkjet printing apparatus, an aerosol printing apparatus, an electrohydrodynamic (EHD) printing apparatus, a nozzle printing apparatus, or a spray coating apparatus.

6. The method of claim 4, wherein the BSM layer comprises silver, copper, gold or aluminum, and the barrier layer comprises nickel, titanium, silicon oxide, aluminum oxide, graphene, boron nitride or molybdenum sulfide.

7. The method of claim 1, further comprising:
forming an underfill encapsulant between the semiconductor die and the substrate.

8. The method of claim 4, further comprising:
providing a thermal interface material (TIM) layer having a bottom TIM surface and a top TIM surface;
attaching the bottom TIM surface to the barrier layer; and
attaching a heatsink to the top TIM surface.

9. The method of claim 8, further comprising:
forming soldering flux on the bottom TIM surface and the top TIM surface,
wherein the bottom TIM surface is attached to the barrier layer via the soldering flux on the bottom TIM surface, and the heatsink is attached to the top TIM surface via the soldering flux on the top TIM surface.

10. The method of claim 8, wherein the heatsink comprises a lid and a surface finish layer attached to the lid, and the heatsink is attached to the TIM layer via the surface finish layer.

11. The method of claim 8, further comprising:
reflowing the TIM layer to solder the TIM layer and the barrier layer together and solder the TIM layer and the heatsink together.

12. The method of claim 8, wherein the TIM layer comprises indium, or an indium-silver alloy.

13. A semiconductor package, comprising:
a substrate;
a semiconductor die mounted on a top surface of the substrate;
a barrier wall formed on a peripheral area of a top surface of the semiconductor die; and
a back side metallization (BSM) layer formed on the top surface of the semiconductor die, wherein the BSM layer is enclosed or partially enclosed with the barrier wall.

14. The semiconductor package of claim 13, further comprising:
a barrier layer formed on the BSM layer, wherein the barrier layer is enclosed or partially enclosed with the barrier wall.

15. The semiconductor package of claim 14, wherein the BSM layer comprises silver, copper, gold or aluminum, and the barrier layer comprises nickel, titanium, silicon oxide, aluminum oxide, graphene, boron nitride or molybdenum sulfide.

16. The semiconductor package of claim 13, further comprising:
an underfill encapsulant formed between the semiconductor die and the substrate.

17. The semiconductor package of claim 14, further comprising:
a thermal interface material (TIM) layer disposed on the barrier layer; and
a heatsink disposed on the TIM layer.

18. The semiconductor package of claim 17, wherein the heatsink comprises a lid and a surface finish layer attached to the lid, and the heatsink is attached to the TIM layer via the surface finish layer.

19. The semiconductor package of claim 17, wherein the TIM layer comprises indium, or an indium-silver alloy.
